(19) United States
(12) Patent Application Publication
(10) Pub. No.: US 2025/0392327 A1
(43) Pub. Date: Dec. 25, 2025

(54) FORWARD ERROR CORRECTION ENCODING USING INTERMEDIATE INFORMATION CORRESPONDING TO MULTIPLE MODULATION SYMBOLS

(71) Applicant: Marvell Asia Pte Ltd, Singapore (SG)

(72) Inventors: Masoud BARAKATAIN, San Jose, CA (US); Jamal RIANI, Best (NL); Trang Minh Tu CAO, Vancouver (CA)

(21) Appl. No.: 19/246,180

(22) Filed: Jun. 23, 2025

Related U.S. Application Data
(60) Provisional application No. 63/663,004, filed on Jun. 21, 2024.

(51) Int. Cl. H03M 13/11; H03M 13/25

(52) U.S. Cl. CPC H03M 13/1105; H03M 13/25

(57) ABSTRACT

Digital signal processing (DSP) circuitry of a transceiver generates intermediate results corresponding to transmit bits that are to be transmitted. Each of at least some of the intermediate results correspond to an encoding of a respective set of multiple bits from amongst the transmit bits. The respective set of multiple bits includes bits corresponding to multiple modulation symbols to be transmitted by the transceiver. The DSP circuitry encodes, according to an FEC code, the intermediate results corresponding to the respective sets of multiple bits to generate parity bits. The DSP circuitry maps, according to a modulation technique, the transmit bits and the parity bits to modulation symbols to generate a digital transmit signal. A digital-to-analog converter (DAC) converts the digital transmit signal to an analog transmit signal.

### CROSS REFERENCES TO RELATED APPLICATIONS

This application claims the benefit of U.S. Provisional Patent App. No. 63/663,004, entitled “SFEC Design with 2D Symbol Mapping,” filed on Jun. 21, 2024, which is incorporated herein by reference in its entirety.

### FIELD OF TECHNOLOGY

The present disclosure relates generally to communication technology, and more particularly to forward error correction encoding.

### BACKGROUND

The approaches described in this background section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

During this time of growth of Internet and artificial intelligence (AI) technologies and usage, demand for high speed data transmission has increased rapidly. For example, the use and expansion of Hyperscale data centers is demanding increasing data transmission rates. Communication technology has evolved to keep up with the demand by providing increasing data rates. For instance, “Terabit Ethernet” (TbE) provides data rates of over 100 gigabits per second (100G): the Institute for Electrical and Electrical Engineers (IEEE) 802.3bs™ Standard defines communication protocols that provide data rates of 200G and 400G; the IEEE 802.3df™ Standard defines a communication protocol that provides a data rate of 800G; and the IEEE 802.3dj™ Standard, now under development, defines a communication protocol that will provide a data rates of 1.6 terabytes per second (1.6 T).

The baud rates of TbE are approaching physical bandwidth limitations of current communication technology. As a result, further increasing baud rates to increase data throughput is problematic.

Communication systems often employ forward error correction (FEC) to reduce bit errors at the receiver and to reduce retransmissions of data due to such bit errors. FEC involves a transmitter generating and transmitting redundant data (sometimes referred to as “parity information”) along with original data to facilitate a receiver recovering the original data when the original data have become corrupted due to channel impairments, noise, interference, etc., experienced during transmission to the receiver. The parity information (redundant data) is considered overhead and effectively reduces data throughput. Generally, increasing the amount of parity data increases error correction robustness but also increases overhead; and decreasing the amount of parity data decreases error correction robustness but also decreases overhead. Although the transmission of parity bits (redundant data) increases overhead, the use of FEC encoding can nonetheless reduce the number of required retransmissions of data and thus effectively increase data throughput when required retransmissions are taken into account, at least in some situations.

Hard-decision FEC decoding involves making hard initial decisions regarding values of received bits and/or modulation symbols, and recovering received data using the hard initial decisions. Soft-decision FEC decoding involves making initial decisions regarding values of received bits and/or modulation symbols with a confidence level such as a probability, sometimes referred to as “soft decisions;” and recovering received data using the soft decisions.

### SUMMARY

In an embodiment, transceiver circuitry for communicating via a communication medium comprises: a communication interface configured to receive transmit bits for transmission via a communication medium; digital signal processing (DSP) circuitry including: encoding circuitry configured to generate intermediate results corresponding to the transmit bits, each of at least some of the intermediate results corresponding to an encoding of a respective set of multiple bits from amongst the transmit bits, the respective set of multiple bits including bits corresponding to multiple modulation symbols to be transmitted by the transceiver, forward error correction (FEC) encoder circuitry configured to encode, according to an FEC code, the intermediate results corresponding to the respective sets of multiple bits to generate parity bits, and mapping circuitry configured to map, according to a modulation technique, the transmit bits and the parity bits to modulation symbols to generate a digital transmit signal; and a digital-to-analog converter (DAC) configured to convert the digital transmit signal to an analog transmit signal.

In another embodiment, a method for error correction encoding in a communication system includes: receiving, at a transceiver, transmit bits for transmission via a communication medium; generating, at the transceiver, intermediate results corresponding to the transmit bits, each of at least some of the intermediate results corresponding to an encoding of a respective set of multiple bits from amongst the transmit bits, the respective set of multiple bits including bits corresponding to multiple modulation symbols to be transmitted by the transceiver; encoding, by the transceiver according to an FEC code, the intermediate results corresponding to the transmit bits to generate parity bits; and mapping, by the transceiver according to a modulation technique, the transmit bits and the parity bits to modulation symbols to be transmitted by the transceiver.

In yet another embodiment, a network device comprises: a processor; a memory coupled to the processor; and transceiver circuitry coupled to the processor. The transceiver circuitry comprises: a communication interface configured to receive transmit bits for transmission via a communication medium; DSP circuitry including: encoding circuitry configured to generate intermediate results corresponding to the transmit bits, each of at least some of the intermediate results corresponding to an encoding of a respective set of multiple bits from amongst the transmit bits, the respective set of multiple bits including bits corresponding to multiple modulation symbols to be transmitted by the transceiver, FEC encoder circuitry configured to encode, according to an FEC code, the intermediate results corresponding to the respective sets of multiple bits to generate parity bits, and mapping circuitry configured to map, according to a modulation technique, the transmit bits and the parity bits to modulation symbols to generate a digital transmit signal; and a DAC configured to convert the digital transmit signal to an analog transmit signal.

### BRIEF DESCRIPTION OF THE DRAWINGS

FIG. 1 is a simplified block diagram of an example transceiver that utilizes forward error correction (FEC) technique for reducing overhead, according to an embodiment.

FIGS. 2A-C are diagrams of an example mapping, performed by the transceiver of FIG. 1, of a set of four transmit bits to a pair of four-level pulse amplitude modulation (PAM4) modulation symbols, according to an embodiment.

FIG. 3A is a simplified block diagram of encoding circuitry of the transceiver of FIG. 1, according to an embodiment.

FIGS. 3B-C are simplified diagrams illustrating respective exclusive OR (XOR) operations performed by the encoding circuitry of FIG. 3A, according to an embodiment.

FIG. 4 is a flow diagram of an example method for error correction encoding performed by the transceiver of FIG. 1, according to an embodiment.

FIG. 5 is a simplified block diagram of a network device including the transceiver of FIG. 1, according to an embodiment.

### DETAILED DESCRIPTION

As mentioned above, increasing baud rates of “Terabit Ethernet” (TbE) is a problematic approach to further increasing data throughput because the current baud rates of TbE are approaching physical bandwidth limitations of current communication technology.

In embodiments described below, communication devices employ example forward error correction (FEC) encoding techniques that reduce overhead while maintaining error recovery robustness as compared to conventional communication devices. For instance, intermediate information is generated (e.g., according to an exclusive-OR (XOR) operation or another suitable logical operation) using sets of multiple bits corresponding to multiple modulation symbols, and parity information is generated using the intermediate information, according to some embodiments. A size of the intermediate information is significantly less than a size of the sets of multiple bits corresponding to multiple modulation symbols, which facilitates reducing a size of the parity information (and thus reducing overhead) as compared to conventional FEC encoding techniques, according to some embodiments. In many communication systems, a probability of multiple independent modulation symbols being in error is very low (e.g., below a target bit error rate (BER) of an output of a FEC decoder), and thus generating the parity information using the intermediate information, which is generated using the sets of multiple bits corresponding to the multiple modulation symbols, does not significantly adversely affect error recovery, at least in some embodiments. In other words, the example FEC encoding techniques described herein reduce overhead while maintaining a desired error recovery performance, according to some embodiments.

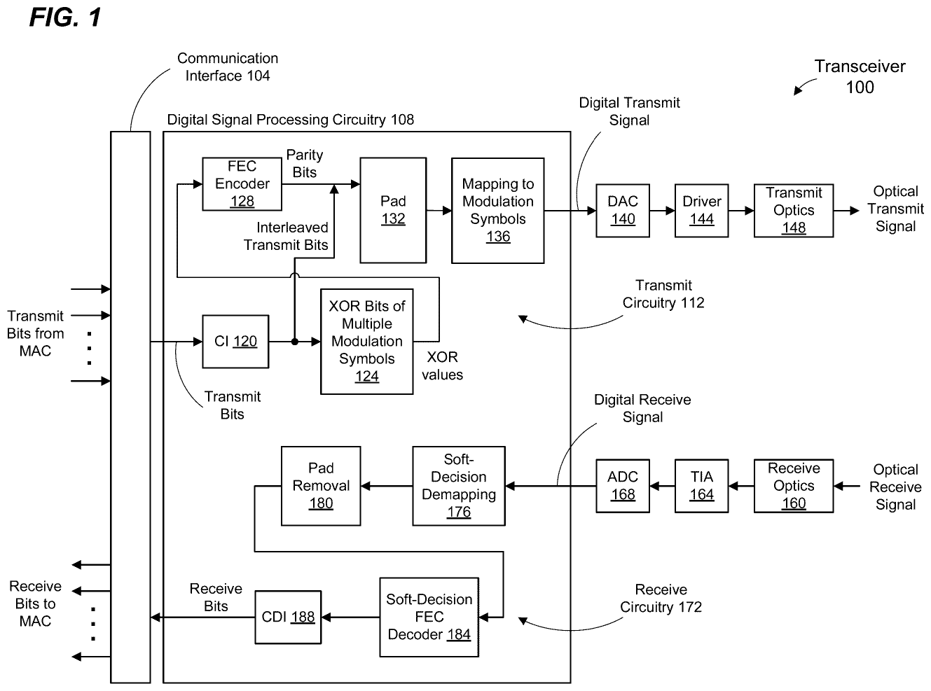

FIG. 1 is a simplified block diagram of an example transceiver 100 that utilizes an innovative FEC technique for reducing overhead, according to an embodiment. The transceiver 100 is configured to transmit data to and receive data from another transceiver (not shown) via a suitable communication medium (not shown) such as a fiber optic cable, an electrical cable, free space, etc. The other transceiver has a suitable structure the same as or similar to the transceiver 100, in an embodiment. In some embodiments, the transceiver 100 is one of a large number of transceivers in an enterprise facility such as data center, and the transceivers facilitate communicating information amongst a large number of network devices, such as one or more of network switches, network routers, network bridges, computers, servers, graphical processing units (GPUs), etc.

The transceiver 100 includes a communication interface 104 that is configured to communicatively couple to a medium access control (MAC) device (not shown) of (or communicatively coupled to) a network device, such as a network switch, a network router, a network bridge, a user computer, a server, a GPU, etc. The communication interface 104 receives transmit bits from the MAC device for transmission by the transceiver 100 via the communication medium, and the communication interface 104 provides receive bits to the MAC device, the receive bits having been recovered by the transceiver 100 from a signal received via the communication medium. FIG. 1 is described with reference to the MAC device for ease of explanation, but in other embodiments the communication interface 104 is configured to communicatively couple to another suitable device other than a MAC device.

In various embodiments, the communication interface 104 comprises a 400 gigabit Ethernet (400G) attachment unit interface (400GAUI) defined by the Institute for Electrical and Electronics Engineers (IEEE) standard 802.3, a 200 gigabit Ethernet (200G) attachment unit interface (200GAUI) defined by the IEEE standard 802.3, a media independent interface (MII), a proprietary communication interface, another suitable communication interface, etc.

As is discussed further below, the transceiver 100 utilizes a FEC encoding technique that reduces overhead as compared to conventional FEC techniques. In some embodiments, the transmit bits received by the communication interface 104 have already been encoded according to a suitable other FEC technique, such as Reed-Solomon (RS) FEC, a low-density parity check (LDPC) FEC, etc. The FEC encoding technique applied by the transceiver 100 is sometimes referred to herein as an “inner FEC,” and the FEC technique already applied to the transmit bits received by the communication interface 104 is sometimes referred to herein as an “outer FEC.”

The communication interface 104 is coupled to digital signal processing (DSP) circuitry 108 (sometimes referred to herein as “the DSP 108”). The communication interface 104 provides transmit bits received from the MAC device to the DSP 108, and the communication interface 104 provides receive bits output by the DSP 108 to the MAC device.

The DSP 108 includes transmit circuitry 112 that is configured to generate a digital transmit signal using the transmit bits. The digital transmit signal corresponds to modulation symbols to be transmitted via the communication medium, and the digital transmit signal is sometimes referred to herein as the “digital transmit modulation symbols signal.”

The DSP 108 also includes receive circuitry 116 that is configured to recover the receive bits from a digital receive signal. The digital receive signal corresponds to modulation symbols received via the communication medium, and the digital receive signal is sometimes referred to herein as the “digital receive modulation symbols signal.”

In an embodiment, the transmit circuitry 112 includes a convolutional interleaver (CI) 120 that is configured to apply a convolutional interleaving operation on the transmit bits received via the communication interface 104. For example, in embodiments in which the transmit bits received via the communication interface 104 comprise FEC codewords (e.g., RS codewords) corresponding to an outer FEC, the CI 120 performs a convolutional interleaving operation so that bits from multiple FEC codewords of the outer FEC are interleaved.

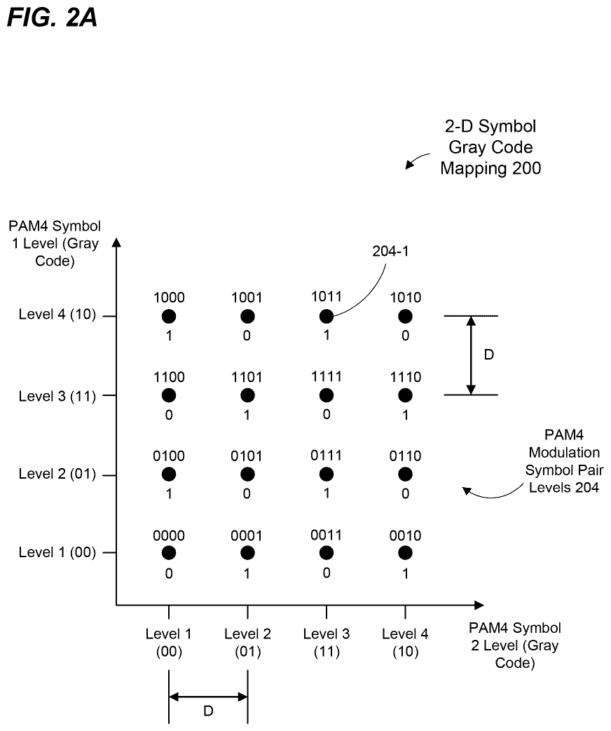

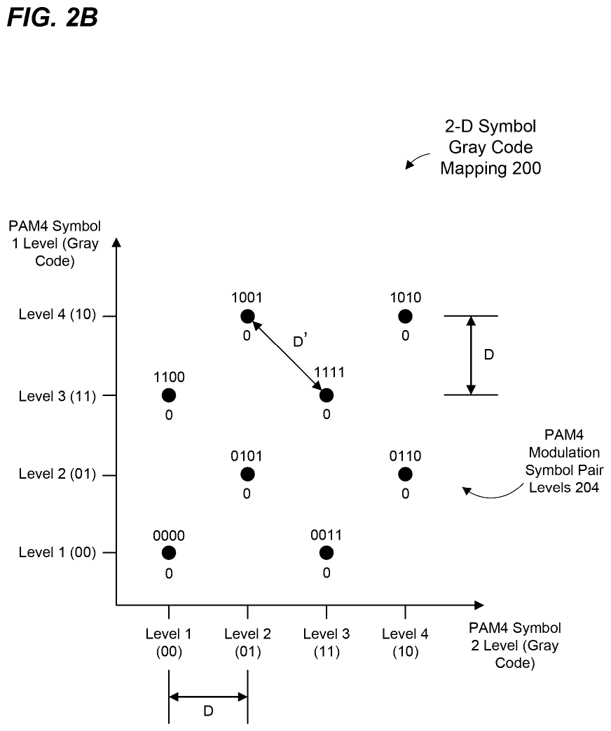

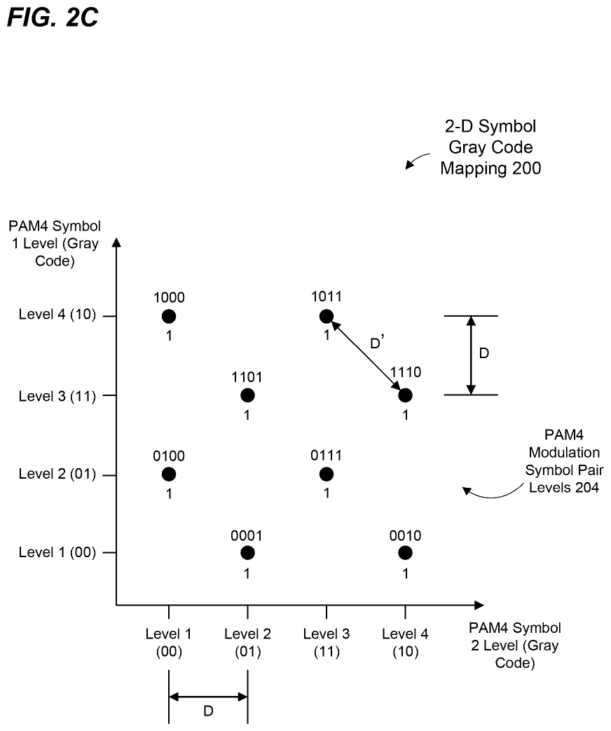

XOR calculation circuitry 124 is coupled to an output of the CI 120. The XOR calculation circuitry 124 is configured to i) select sets of multiple bits from amongst the transmit bits output by the CI 120, each set of multiple bits including bits corresponding to multiple modulation symbols to be transmitted by the transceiver 100 via the communication medium, and ii) generate, for each set of multiple bits, a respective XOR result. Operation of the XOR calculation circuitry 124 is described with reference to FIGS. 2A-C. In other embodiments, another suitable encoding different than XOR encoding is employed, such as a hash function encoding, a cyclic redundancy check (CRC) encoding, etc. In such embodiments, encoding circuitry is configured to i) select sets of multiple bits from amongst the transmit bits output by the CI 120, each set of multiple bits including bits corresponding to multiple modulation symbols to be transmitted by the transceiver 100 via the communication medium, and ii) generate, for each set of multiple bits, a respective encoding of the set of multiple bits, such as a hash function encoding, a CRC encoding, etc.

FIG. 2A is a diagram of an example mapping 200 of a set of four transmit bits to a pair of four-level pulse amplitude modulation (PAM4) modulation symbols (PAM4 Symbol 1 and PAM4 Symbol 2), according to an embodiment. The PAM4 Symbol 1 and the PAM4 Symbol 2 correspond to different PAM4 modulation symbols transmitted by the transceiver 100 at different times. In some embodiments, such as in environments in which noise associated with successive modulation symbols is correlated, one or more PAM4 modulation symbols are transmitted between the PAM4 Symbol 1 and the PAM4 Symbol 2 in time so that noise associated with the PAM4 Symbol 1 and the PAM4 Symbol 2 is uncorrelated. In other embodiments, such as in environments in which noise associated with successive modulation symbols is uncorrelated (e.g., such as additive white Gaussian noise), the PAM4 Symbol 1 and the PAM4 Symbol 2 are transmitted successively in time.

The vertical axis in FIG. 2A corresponds to possible levels of the PAM4 Symbol 1, and the horizontal axis in FIG. 2A corresponds to possible levels of the PAM4 Symbol 2. Each point 204 corresponds to a respective pair of levels of the PAM4 Symbol 1 and the PAM4 Symbol 2. For example, the point 204-1 corresponds to the PAM4 Symbol 1 having a level of four and the PAM4 Symbol 2 having a level of three.

The respective four bit value above each PAM4 symbol pair value indicates a set of transmit bit values that map to the pair of PAM4 symbol values. The mapping 200 corresponds to a Gray code in that the sets of bit values corresponding to horizontally adjacent points 204 differ by only one bit, and the sets of bit values corresponding to vertically adjacent points 204 also differ by only one bit.

The respective one bit value below each PAM4 symbol pair value is a result (an “XOR value”) of performing an XOR operation on the respective set of bits above the PAM4 symbol pair value. For example, the XOR calculation circuitry 124 generates the XOR value, in an embodiment. As can be seen in FIG. 2A, horizontally adjacent points 204 have different XOR values, and vertically adjacent points 204 also have different XOR values. Horizontally adjacent points 204 are separated by a distance D, and vertically adjacent points 204 are also separated by the distance D.

FIG. 2B is a diagram showing only the points 204 corresponding to the XOR value zero. The distance between adjacent points 204 corresponding to the XOR value zero is D′, which is 3 decibels (dB) greater than the distance D. Therefore, if a receiver is able to correctly determine the XOR value corresponding to a pair of PAM4 modulation symbols 204, there is a 3 dB increase in distance between adjacent points 204 as compared to the distance D between adjacent points 204 in the diagram of FIG. 2A. Similarly, FIG. 2C is a diagram showing only the points 204 corresponding to the XOR value one. The distance between adjacent points 204 corresponding to the XOR value one is D′, which is 3 dB greater than the distance D.

Referring now to FIGS. 1 and 2A-C, the XOR calculation circuitry 124 selects the bits corresponding to a pair of PAM4 modulation symbol values (e.g., bits corresponding to the PAM4 Symbol 1 and the PAM4 Symbol 2) and generates an XOR value by performing an XOR operation on the bits corresponding to the pair of PAM4 modulation symbol values, according to an embodiment. For example, the XOR calculation circuitry 124 selects bits corresponding to the PAM4 Symbol 1 and the PAM4 Symbol 2 and generates the XOR values illustrated in FIGS. 2A-C, in an embodiment.

An FEC encoder 128 encodes the XOR values according to an FEC code to generate parity bits. In an embodiment, the FEC encoder 128 is configured to employ a Bose-Chaudhuri-Hocquenghem (BCH) code to encode the XOR values. In other embodiments, the FEC encoder 128 is configured to employ another suitable FEC code.

An amount of the XOR values (an example of intermediate information discussed above) is significantly less than an amount of bits corresponding to the pair of PAM4 modulation symbols, which facilitates reducing a size of the parity information generated by the FEC encoder 128 (and thus reducing overhead) as compared to conventional FEC encoding techniques, according to some embodiments. In many communication systems, a probability of both the PAM4 Symbol 1 and the PAM4 Symbol 2 being in error is very low (e.g., below a target BER of an output of a FEC decoder), and thus generating the parity information using the XOR values does not significantly adversely affect error recovery, at least in some embodiments. In other words, generating the parity information using the XOR values reduces overhead while maintaining a desired error recovery performance as compared to conventional FEC encoding techniques, according to some embodiments.

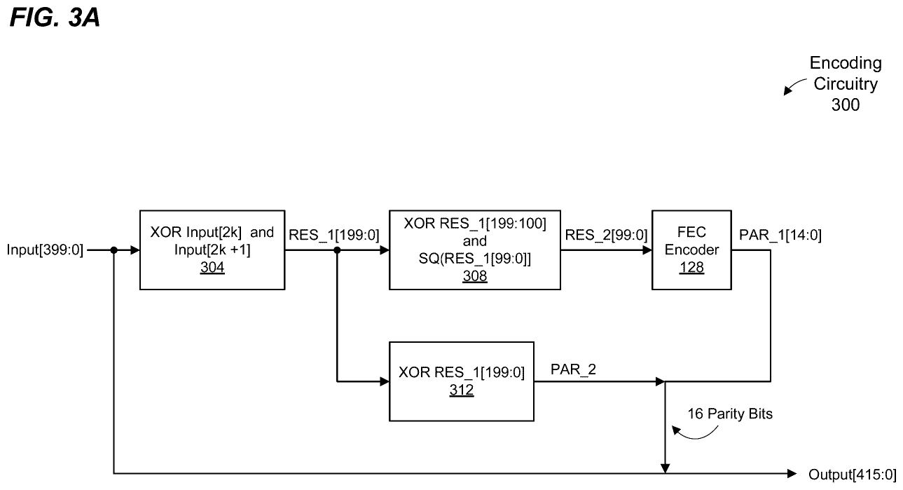

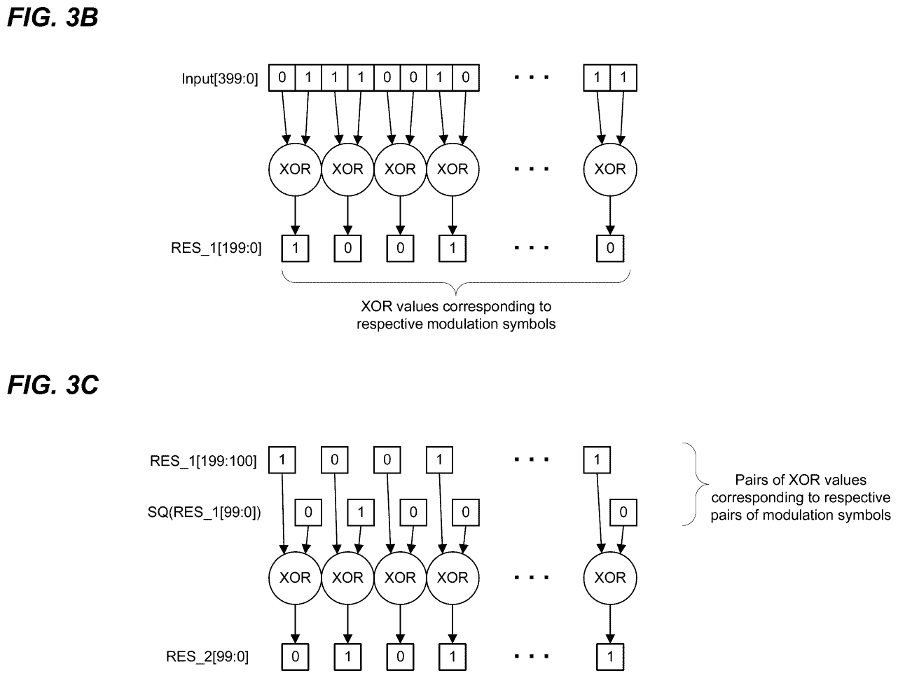

FIG. 3A is a simplified block diagram of encoding circuitry 300 that corresponds to the XOR calculation circuitry 124 and the FEC encoder 128 of FIG. 1, according to an embodiment. In other embodiments, the XOR calculation circuitry 124 and the FEC encoder 128 of FIG. 1 are implemented using circuitry different than the encoding circuitry 300. In other embodiments, the encoding circuitry 300 is included in a suitable transceiver different than the transceiver 100 of FIG. 1.

In the example of FIG. 3A, the encoding circuitry 300 is configured to process blocks of 400 input bits (Input[399:0]) to generate respective blocks of 416 output bits (Output[415:0]), each of which includes the respective original 400 input bits and a respective set of 16 parity bits. In other embodiments, the encoding circuitry 300 is configured to process blocks of input bits having a suitable size other than 400 and/or to generate a suitable number of parity bits other than 16. The input bits correspond to information bits that are to be encoded onto modulation symbols for transmission via a communication medium. For example, the first circuitry 304 receives input bits that are to be modulated on PAM4 modulation symbols, in an embodiment.

First circuitry 304 is configured to receive input bits and to perform XOR operations on respective pairs of adjacent input bits to generate respective XOR values corresponding to a first intermediate result (RES_1[199:0]). For example, the first circuitry 304 implements:

$$RES\_ 1 [ k ] = Input [ 2 k ] XOR Input [ 2 k + 1 ] \qquad ( Equation 1 )$$

where k is an index that ranges from 0 to 199. In the example of FIG. 3A, the first circuitry 304 processes a block of 400 input bits to generate an intermediate result of 200 bits (RES_1[199:0]). The operation performed by the first circuitry 304 corresponds to, for each set of bits corresponding to a respective PAM4 modulation symbol, performing an XOR on the set of bits to generate a respective XOR value that corresponds to the PAM4 modulation symbol, in an embodiment.

FIG. 3B is a diagram illustrating operation of the first circuitry 304. Each pair of adjacent bits in the input bits (Input[399:0]) corresponds to a respective PAM4 modulation symbol, and respective XOR operations are performed on the respective pairs of adjacent bits to generate respective XOR values (RES_1[199:0]) that correspond to the respective PAM4 modulation symbols.

Referring again to FIG. 3A, second circuitry 308 is configured to receive the first intermediate result (RES_1[199:0]), which includes a first portion (RES_1[199:100]) and a second portion (RES_1[99:0]), reorder the second portion according to a bit reordering operation SQ, and perform XOR operations on respective pairs of bits from the first portion and the reordered second portion to generate respective XOR values corresponding to a second intermediate result (RES_2[99:0]). For example, the first circuitry 304 implements:

$$RES\_ 2 [ k ] = RES\_ 1 [ k + 100 ] XOR SQ ( RES\_ 1 [ k ] ) \qquad ( Equation 2 )$$

where k is an index that ranges from 0 to 99. The bit reordering operation SQ corresponds to selecting a bits from the second portion (RES_1[99:0]) to be paired with respective bits from the first portion (RES_1[199:100]) for performing the XOR operation of Equation 2. Additionally, the bit reordering operation SQ corresponds to selecting respective sets of XOR values corresponding to respective sets of different modulation symbols for performing the XOR operation of Equation 2. The operation performed by the second circuitry 308 corresponds to, for each set of XOR values corresponding to a respective pair of PAM4 modulation symbols, performing an XOR on the set of XOR values to generate a respective XOR result that corresponds to the respective pair of PAM4 modulation symbols, in an embodiment.

FIG. 3C is a diagram illustrating operation of the second circuitry 308. Each bit of the first portion (RES_1[199:100]) is paired with a respective bit from the reordered second portion (SQ(RES_1[99:0])), and respective XOR operations are performed on the respective pairs of bits to generate respective XOR values RES_2[99:0] that correspond to respective pairs of PAM4 modulation symbols.

Referring again to FIG. 3A, the FEC encoder 128 encodes the second intermediate result (RES_2[99:0]) according to an FEC code to generate parity bits. For example, the FEC encoder 128 encodes the second intermediate result (RES_2[99:0]) according to a (115,100) BCH code to generate 15 parity bits PAR_1[14:0]. In other embodiments, the FEC encoder 128 applies another suitable code different than a BCH code and/or generates another suitable number of parity bits different than 15.

Third circuitry 312 is configured to receive the 400 input bits and to perform an XOR operation on all of the 400 input bits to generate another parity bit PAR_2.

The parity bits PAR_1 and PAR_2 are appended to the 400 input bits to provide the output bits (Output[415:0]).

In other embodiments, the encoding circuitry operates on a number of bits different than 400 and/or generates another suitable number of parity bits different than 16.

In some embodiments, the first circuitry 304 is omitted. For example, in some embodiments in which each modulation symbol conveys a single bit (e.g., such as with two-level pulse amplitude modulation (PAM2)), the first circuitry 304 is omitted.

In some embodiments, the second circuitry 308 is configured to encode bits corresponding to more than two modulation symbols (e.g. three modulation symbols, four modulation symbols, five modulation symbols, etc.). For example, the second circuitry 308 is configured to receive the first intermediate result (RES_1[199:0]), which includes more than two portions, reorder at least two portions according to respective bit reordering operations, and perform XOR operations on respective tuples of bits from the more than two portions to generate respective XOR values corresponding to a second intermediate result.

Referring again to FIG. 1, the parity bits are appended to the interleaved transmit bits output by the CI 120, and the interleaved transmit bits and the parity bits are provided to padding circuitry 132.

The padding circuitry 132 selectively adds padding bits to the interleaved transmit bits and the parity bits so that a line rate of an output of the transceiver 100 is at a desired rate. For example, the padding circuitry 132 selectively adds padding bits so that a line rate of an output of the transceiver 100 is at a multiple of 156.25 MHz, as merely an illustrative example. In other embodiments, the padding circuitry 132 selectively adds padding bits so that line rate of the output of the transceiver 100 is at a desired rate that is not a multiple of 156.25 MHz.

Symbol mapping circuitry 136 maps transmit bits, parity bits, and padding bits to modulation symbols to generate a digital transmit signal, which is output by the DSP 108. For example, the symbol mapping circuitry 136 maps transmit bits, parity bits, and padding bits to PAM4 symbols, in an embodiment. In other embodiments, the symbol mapping circuitry 136 maps transmit bits, parity bits, and padding bits to other suitable modulation symbols, such as 8-level PAM modulation (PAM8) symbols, quadrature amplitude modulation (QAM) symbols, N-constellation QAM (N-QAM) symbols, etc. A digital-to-analog converter (DAC) 140 converts the digital transmit signal to an analog transmit signal. Driver circuitry 144 generates an analog drive signal based on the analog transmit signal output by the DAC 140, the analog drive signal configured to drive a laser to generate optical transmit modulation symbols, such as optical PAM4 modulation symbols or other suitable modulation symbols. Transmit optics 148, which include the laser, receives the analog drive signal and generates, based on the analog drive signal, an optical transmit signal having the optical transmit modulation symbols. The transmit optics 148 are optically coupled to an optical medium, and the optical transmit signal is transmitted via the optical medium to a link partner.

In an embodiment, the DAC 140 and/or the driver circuitry 144 correspond to analog front end (AFE) circuitry.

In an embodiment, the link partner includes a transceiver the same as or similar to the transceiver 100. The transceiver of the link partner is configured to perform an encoding process such as described above for an optical signal that the transceiver of the link partner transmits to the transceiver 100 via the optical medium (or another optical medium). The transceiver 100 receives the optical signal transmitted by the other transceiver, and thus the optical signal transmitted by the other transceiver is sometimes referred to herein as an “optical receive signal.”

The transceiver 100 includes receive optics 160 that are optically coupled to the optical medium (or the other optical medium) and are configured to receive the optical receive signal via the optical medium (or the other optical medium). The optical receive signal includes optical modulation symbols (sometimes referred to herein as “optical receive modulation symbols”) that were transmitted by the link partner. The receive optics 160 are configured to convert the optical receive signal to an analog electrical signal. For example, the receive optics 160 include a photodiode that is configured to convert the optical receive signal to an analog electrical current signal.

A transimpedance amplifier (TIA) 164 is coupled to the receive optics 160 and is configured to convert the analog electrical current signal to an analog electrical voltage signal. An analog-to-digital converter (ADC) 158 is configured to convert the analog electrical voltage signal to a digital receive signal, which is provided to the DSP 108.

The DSP 108 includes receive circuitry 172 that is configured to extract receive bits that were modulated, by the link partner, on the optical receive modulation symbols. The receive circuitry 172 includes soft-decision demapping circuitry 176 that is configured to generate initial decisions regarding demappings of the receive modulation symbols to respective sets of bits. Each of at least some of the initial decisions includes i) an indication of a respective modulation symbol value that was decided from amongst a set of possible modulation symbol values, and ii) an indicator of a confidence level of the decision, in an embodiment. For example, for each of at least some of receive modulation symbols, the soft-decision demapping circuitry 176: determines a modulation symbol value, from amongst the set of possible modulation symbol values, that has a shortest distance to the receive modulation symbol; selects as the initial decision the determined modulation symbol value; and determines the confidence level of the decision based on the distance between the receive modulation symbol and the determined modulation symbol value, according to an embodiment. In an embodiment, the soft-decision demapping circuitry 176 is configured to generate initial decisions regarding demappings of PAM4 symbols. In other embodiments, the soft-decision demapping circuitry 176 is configured to generate initial decisions regarding demappings of other suitable modulation symbols, such as PAM8 symbols, QAM symbols, N-QAM symbols, etc.

In an embodiment, for each decision, the indication of the respective modulation symbol value includes a set of bit values corresponding to the modulation symbol value decided by the soft-decision demapping circuitry 176. For example, the possible modulation symbol values correspond to respective sets of bit values, and indication of the respective modulation symbol value chosen for a receive modulation symbol includes the set of bit values that correspond to the respective modulation symbol value, in an embodiment.

In some embodiments in which the receive modulation symbols are PAM4 modulation symbols, the soft-decision demapping circuitry 176 is configured to, for each of at least some of the receive PAM4 modulation symbols, i) determine a respective PAM4 level value, from amongst a set of possible PAM4 level values; ii) select as the initial decision the determined PAM4 level value; and iii) determine the confidence level of the decision based on the distance between the receive PAM4 modulation symbol and the determined PAM4 level value, according to an embodiment.

In an embodiment, the soft-decision demapping circuitry 176 includes slicer circuitry that is configured to: i) determine a modulation symbol value, from amongst the set of possible modulation symbol values, that has a shortest distance to the receive modulation symbol; ii) select as the initial decision the determined modulation symbol value; and iii) determine the confidence level of the decision based on the distance between the receive modulation symbol and the determined modulation symbol value, according to an embodiment.

In an embodiment, an output of the soft-decision demapping circuitry 176 includes initial decisions and respective indications of confidence levels for i) receive bits (e.g., information bits), ii) parity bits, and iii) in embodiments in which the link partner adds padding bits (such as described above with reference to the padding circuitry 132), padding bits.

In embodiments in which the link partner adds padding bits, padding removal circuitry 180 is configured to remove, from the output of the soft-decision demapping circuitry 176, initial decisions and respective indications of confidence levels corresponding to the padding bits.

A soft-decision FEC decoder 184 is configured to perform a soft-decision FEC decoding operation using the initial decisions and respective indications of confidence levels for i) the receive bits (e.g., information bits), and ii) the parity bits. In an embodiment in which the parity bits are encoded using a BCH code, the soft-decision FEC decoder 184 is configured to perform a soft-decision FEC decoding operation according to the BCH code.

A convolutional deinterleaver (CDI) 188 is configured to apply a convolutional deinterleaving operation on the bits received via the communication interface 104. The convolutional deinterleaving operation corresponds to a reverse of the convolutional interleaving operation performed by the CI 120, in an embodiment. For example, in embodiments in which the bits output by the soft-decision FEC decoder 184 comprise FEC codewords (e.g., RS codewords) corresponding to an outer FEC, the CDI 188 performs a deinterleaving operation so that bits from multiple FEC codewords of the outer FEC are deinterleaved.

The receive circuitry 172 outputs FEC codewords of the outer FEC via the communication interface 104. For example, the FEC codewords output by the receive circuitry 172 are transferred to the MAC device via the communication interface 104, in an embodiment. The FEC codewords output by the receive circuitry 172 are transferred to a suitable device other than a MAC device via the communication device 104.

Although FIGS. 1, 2A-C, and 3A-C were discussed in the context of optical communications, similar techniques can be used in other types of communication systems such as electrical communication systems, wireless communication systems, satellite communication systems, etc. For instance, in a system in which the communication medium comprises an electrical cable, the driver 144, the transmit optics 148, the receive optics 160, and the TIA 164 are replaced by analog front end (AFE) circuitry that includes one or more amplifiers, one or more filters, etc., in an embodiment. In a system in which the communication medium comprises free space in the context of electrical wireless communication, the driver 144, the transmit optics 148, the receive optics 160, and the TIA 164 are replaced by one or more wireless transceivers, which are coupled to one or more antennas, in an embodiment.

Although FIGS. 1, 2A-C, and 3A-C were discussed in the context of encoding using XOR, other suitable types of encoding (e.g., hash function encoding, CRC encoding, etc.) are used in other embodiments. For instance, the circuitry 124 of FIG. 1 is replaced with circuitry that performs another suitable type of encoding (e.g., hash function encoding, CRC encoding, etc.), in other embodiments. As another example, the circuitry 304, the circuitry 308, and/or the circuitry 312 of FIG. 3A are replaced with circuitry that performs another suitable type of encoding (e.g., hash function encoding, CRC encoding, etc.), in other embodiments. Similarly, the XOR encoding of FIG. 3B and/or the XOR encoding of FIG. 3C are replaced with another suitable type of encoding (e.g., hash function encoding, CRC encoding, etc.), in other embodiments.

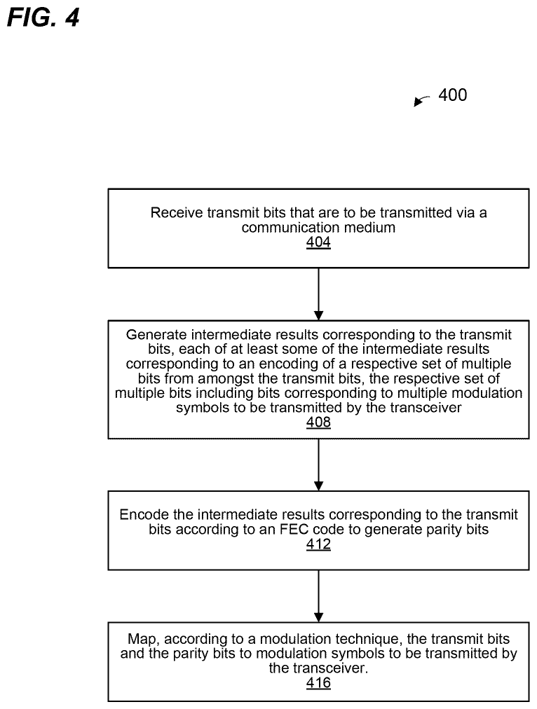

FIG. 4 is a flow diagram of an example method 400 for error correction encoding in a communication system, according to an embodiment. The method 400 is implemented by the transceiver 100 of FIG. 1, according to an embodiment, and the method 400 is described with reference to FIG. 1 for ease of explanation. In other embodiments, the method 400 is implemented by another suitable transceiver different than the example transceiver 100 of FIG. 1. Additionally, the transceiver 100 does not implement the method 400 and/or implements another suitable method for error correction encoding different than the method 400, in some embodiments.

At block 404, a transceiver receives transmit bits that are to be transmitted via a communication medium. For example, the communication interface 104 receives transmit bits that that are to be transmitted via a communication medium.

At block 408, the transceiver generates intermediate results corresponding to the transmit bits, each of at least some of the intermediate results corresponding to an encoding of a respective set of multiple bits from amongst the transmit bits, the respective set of multiple bits including bits corresponding to multiple modulation symbols to be transmitted by the transceiver.

In another embodiment, the intermediate results are first intermediate results, and generating the intermediate results at block 408 comprises: generating, by the transceiver, second intermediate results corresponding to the transmit bits, each of at least some of the second intermediate results corresponding to an encoding of a respective subset of multiple bits from amongst the transmit bits, the respective subset of multiple bits including bits corresponding to a respective modulation symbol amongst the modulation symbols to be transmitted by the transceiver; and generating, by the transceiver, the first intermediate results using the second intermediate results, each of at least some of the first intermediate results corresponding to an encoding of a respective set of multiple second intermediate results, the respective set of second intermediate results including second intermediate XOR results that correspond to multiple modulation symbols to be transmitted by the transceiver.

In another embodiment, generating the intermediate results at block 408 comprises generating, by the transceiver, XOR results corresponding to the transmit bits, each of at least some of the XOR results corresponding to an XOR of a respective set of multiple bits from amongst the transmit bits, the respective set of multiple bits including bits corresponding to multiple modulation symbols to be transmitted by the transceiver.

In another embodiment, generating the XOR results at block 408 comprises: generating, by the transceiver, intermediate XOR results corresponding to the transmit bits, each of at least some of the intermediate XOR results corresponding to an XOR of a respective subset of multiple bits from amongst the transmit bits, the respective subset of multiple bits including bits corresponding to a respective modulation symbol amongst the modulation symbols to be transmitted by the transceiver; and generating, by the transceiver, the XOR results using the intermediate XOR results, each of at least some of the XOR results corresponding to an XOR of a respective set of multiple intermediate XOR results, the respective set of intermediate XOR results including intermediate XOR results that correspond to multiple modulation symbols to be transmitted by the transceiver.

At block 412, the transceiver encodes the intermediate results corresponding to the transmit bits according to a forward error correction (FEC) code to generate parity bits. In an embodiment in which encoding the intermediate results at block 408 comprises generating XOR results, encoding the intermediate results at block 412 comprises encoding XOR results.

In another embodiment in which generating the intermediate results at block 408 comprises generating second intermediate results, the method 400 further includes: generating, by the transceiver, an additional parity bit using the second intermediate results, the additional parity bit corresponding to an encoding of the second intermediate results.

In another embodiment in which block 408 comprises generating intermediate XOR results, the method 400 further includes: generating, by the transceiver, an additional parity bit using the intermediate XOR results, the additional parity bit corresponding to an XOR of the intermediate XOR results.

At block 416, the transceiver maps, according to a modulation technique, the transmit bits and the parity bits to modulation symbols to be transmitted by the transceiver.

In another embodiment, the method 400 further comprises generating, by the transceiver, FEC codewords, each FEC codeword including a respective group of N transmit bits, wherein N is a positive integer greater than one; generating the intermediate results at block 408 comprises generating, for each of at least some of the FEC codewords, a respective set of intermediate results corresponding to the respective group of N transmit bits; encoding the intermediate results according to the FEC code at block 412 comprises, for each of the at least some of the FEC codewords, encoding, according to the FEC code, the respective set of intermediate results to generate P parity bits for the FEC codeword, wherein P is a positive integer greater than one; and mapping the transmit bits and the parity bits to modulation symbols at block 416 comprises mapping, according to the modulation technique, the FEC codewords to the modulation symbols.

In an embodiment N is 400. In other embodiments, N is another suitable positive integer.

In an embodiment, P is 15. In other embodiments, P is another suitable positive integer.

In an embodiment, N is 400 and P is 15.

In an embodiment, encoding the intermediate results according to the FEC code at block 412 comprises encoding the intermediate results according to a BCH code to generate the parity bits. In other embodiments, encoding the intermediate results according to the FEC code at block 412 comprises encoding the intermediate results according to another suitable FEC code different than a BCH code.

In an embodiment, mapping the transmit bits and the parity bits to modulation symbols at block 416 comprises mapping, according to a PAM technique, the transmit bits and the parity bits to PAM modulation symbols to generate the digital transmit signal.

In an embodiment, mapping the transmit bits and the parity bits to modulation symbols at block 416 comprises: mapping, according to a PAM4 technique, the transmit bits and the parity bits to PAM4 modulation symbols to generate the digital transmit signal.

In another embodiment, mapping the transmit bits and the parity bits to modulation symbols at block 416 comprises: mapping, according to an 8-level PAM (PAM8) technique, the transmit bits and the parity bits to PAM8 modulation symbols to generate the digital transmit signal.

In other embodiments, mapping the transmit bits and the parity bits to modulation symbols at block 416 comprises mapping the transmit bits and the parity bits to modulation symbols according to another suitable modulation technique different than PAM.

In another embodiment, the method 400 further comprises converting, by a digital-to-analog converter (DAC), the digital transmit signal to an analog transmit signal.

In another embodiment, the method 400 further comprises generating, by transmit optics that include a laser, an optical transmit signal for transmission via an optical communication medium based on the analog transmit signal.

The transceivers, techniques, etc., described above are included and/or implemented in a network device such as a network switch, a network bridge, an access point, a modem, a computer (e.g., a server), etc. Such a network device includes one or more processors, one or more memories, and one or more transceivers such as described herein, in an embodiment.

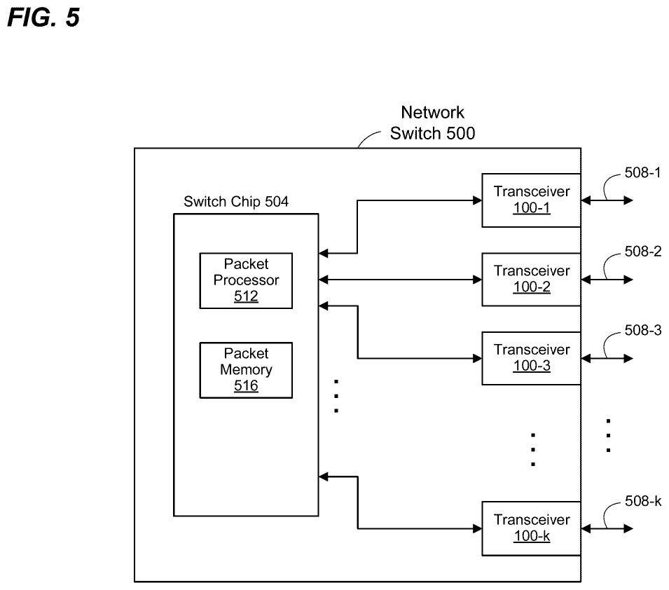

FIG. 5 is a simplified block diagram of an example network switch 500 that includes transceivers that utilize an innovative FEC technique for reducing overhead, in an embodiment. The network switch 500 includes a plurality of transceivers 100 such as discussed above with reference to FIG. 1 or other transceivers described herein, in an embodiment. In another embodiment, the network switch 500 includes a plurality of suitable transceivers different than the transceiver 100.

The network switch 500 comprises a switch integrated circuit (IC) chip 504 (the “switch chip 504”) coupled to the plurality of transceivers 100, and each transceiver 100 is coupled to a respective communication medium, such as an optical fiber, free space, etc. FIG. 5 illustrates k transceivers coupled to k optical media, where k is a suitable positive integer.

The switch chip 504 includes a plurality of internal network interfaces (not shown) communicatively coupled to the transceivers 100. The switch chip 504 also includes other components such as a packet processor 512 to analyze at least packet header data of packets received via the internal network interfaces to determine internal network interfaces via which the packet are to be forwarded, a packet memory 516 to store packet data while packets are analyzed by the packet processor 512, etc.

The switch chip 504 is included within in a suitable chip package having suitable external interconnect structures for inputting and outputting signals to/from the switch chip 504, such as a ball grid array (BGA), a pin grid array (PGA), etc.

Although one switch chip 504 is illustrated in FIG. 5, the network device 500 includes multiple switch chips 504 coupled to respective subsets of the transceivers 100, in other embodiments.

In a system in which the communication media comprise electrical cables, the driver 144, the transmit optics 148, the receive optics 160, and the TIA 164 of the transceivers 100 are replaced by AFE circuitry that includes one or more amplifiers, one or more filters, etc., in an embodiment.

Embodiment 1: Transceiver circuitry for communicating via a communication medium, comprising: a communication interface configured to receive transmit bits for transmission via a communication medium; digital signal processing (DSP) circuitry including: encoding circuitry configured to generate intermediate results corresponding to the transmit bits, each of at least some of the intermediate results corresponding to an encoding of a respective set of multiple bits from amongst the transmit bits, the respective set of multiple bits including bits corresponding to multiple modulation symbols to be transmitted by the transceiver, forward error correction (FEC) encoder circuitry configured to encode, according to an FEC code, the intermediate results corresponding to the respective sets of multiple bits to generate parity bits, and mapping circuitry configured to map, according to a modulation technique, the transmit bits and the parity bits to modulation symbols to generate a digital transmit signal; and a digital-to-analog converter (DAC) configured to convert the digital transmit signal to an analog transmit signal.

Embodiment 2: The transceiver circuitry of embodiment 1, wherein the intermediate results are first intermediate results, and wherein the encoding circuitry comprises: first circuitry configured to generate second intermediate results corresponding to the transmit bits, each of at least some of the second intermediate results corresponding to an encoding of a respective subset of multiple bits from amongst the transmit bits, the respective subset of multiple bits including bits corresponding to a respective modulation symbol amongst the modulation symbols to be transmitted by the transceiver; and second circuitry configured to generate the first intermediate results using the second intermediate results, each of at least some of the first intermediate results corresponding to an encoding of a respective set of multiple second intermediate results, the respective set of second intermediate results including second intermediate results that correspond to multiple modulation symbols to be transmitted by the transceiver.

Embodiment 3: The transceiver circuitry of embodiment 2, wherein the encoding circuitry further comprises third circuitry configured to generate an additional parity bit using the second intermediate results, the additional parity bit corresponding to an encoding of the second intermediate results; and wherein the mapping circuitry is configured to map, according to the modulation technique, the transmit bits, the parity bits, and the additional parity bit to the modulation symbols to generate the digital transmit signal.

Embodiment 4: The transceiver circuitry of embodiment 1, wherein the encoding circuitry comprises exclusive-OR (XOR) calculation circuitry configured to generate XOR results corresponding to the transmit bits, each of at least some of the XOR results corresponding to an XOR of a respective set of multiple bits from amongst the transmit bits, the respective set of multiple bits including bits corresponding to multiple modulation symbols to be transmitted by the transceiver; and wherein the FEC encoder circuitry configured to encode, according to the FEC code, the XOR results corresponding to the respective sets of multiple bits to generate the parity bits.

Embodiment 5: The transceiver circuitry of embodiment 4, wherein the XOR calculation circuitry comprises: first circuitry configured to generate intermediate XOR results corresponding to the transmit bits, each of at least some of the intermediate XOR results corresponding to an XOR of a respective subset of multiple bits from amongst the transmit bits, the respective subset of multiple bits including bits corresponding to a respective modulation symbol amongst the modulation symbols to be transmitted by the transceiver; and second circuitry configured to generate the XOR results using the intermediate XOR results, each of at least some of the XOR results corresponding to an XOR of a respective set of multiple intermediate XOR results, the respective set of intermediate XOR results including intermediate XOR results that correspond to multiple modulation symbols to be transmitted by the transceiver.

Embodiment 6: The transceiver circuitry of embodiment 5, wherein the XOR calculation circuitry further comprises third circuitry configured to generate an additional parity bit using the intermediate XOR results, the additional parity bit corresponding to an XOR of the intermediate XOR results; and wherein the mapping circuitry is configured to map, according to the modulation technique, the transmit bits, the parity bits, and the additional parity bit to the modulation symbols to generate the digital transmit signal.

Embodiment 7: The transceiver circuitry of any of embodiments 1-6, wherein: the DSP circuitry is configured to generate FEC codewords, each FEC codeword including a respective group of N transmit bits, wherein N is a positive integer greater than one; the encoding circuitry is configured to generate, for each of at least some of the FEC codewords, a respective set of intermediate results corresponding to the respective group of N transmit bits; the FEC encoder circuitry is configured to, for each of the at least some of the FEC codewords, encode, according to the FEC code, the respective set of intermediate results to generate P parity bits for the FEC codeword, wherein P is a positive integer greater than one; and the mapping circuitry configured to map, according to the modulation technique, the FEC codewords to the modulation symbols.

Embodiment 8: The transceiver circuitry of embodiment 7, wherein N is 400.

Embodiment 9: The transceiver circuitry of either of embodiments 7 or 8, wherein P is 15.

Embodiment 10: The transceiver circuitry of any of embodiments 1-9, wherein the FEC encoder circuitry is configured to encode the intermediate results according to a Bose-Chaudhuri-Hocquenghem (BCH) code to generate the parity bits.

Embodiment 11: The transceiver circuitry of any of embodiments 1-10, wherein the mapping circuitry is configured to: map, according to a pulse amplitude modulation (PAM) technique, the transmit bits and the parity bits to PAM modulation symbols to generate the digital transmit signal.

Embodiment 12: The transceiver circuitry of embodiment 11, wherein the mapping circuitry is configured to: map, according to a 4-level pulse amplitude modulation (PAM4) technique, the transmit bits and the parity bits to PAM4 modulation symbols to generate the digital transmit signal.

Embodiment 13: The transceiver circuitry of any of embodiments 1-12, further comprising: transmit optics coupled to the DAC, the transmit optics including a laser, the transmit optics configured to generate, based on the analog transmit signal and an output of the laser, an optical transmit signal for transmission via an optical communication medium.

Embodiment 14: The transceiver circuitry of any of embodiments 1-12, further comprising: analog front end (AFE) circuitry coupled to the DAC, the AFE circuitry configured to generate, based on the analog transmit signal, an electrical transmit signal for transmission via a communication medium.

Embodiment 15: A method for error correction encoding in a communication system, the method comprising: receiving, at a transceiver, transmit bits for transmission via a communication medium; generating, at the transceiver, intermediate results corresponding to the transmit bits, each of at least some of the intermediate results corresponding to an encoding of a respective set of multiple bits from amongst the transmit bits, the respective set of multiple bits including bits corresponding to multiple modulation symbols to be transmitted by the transceiver; encoding, by the transceiver according to a forward error correction (FEC) code, the intermediate results corresponding to the transmit bits to generate parity bits; and mapping, by the transceiver according to a modulation technique, the transmit bits and the parity bits to modulation symbols to be transmitted by the transceiver.

Embodiment 16: The method for error correction encoding of embodiment 15, wherein the intermediate results are first intermediate results, and wherein generating the first intermediate results comprises: generating, at the transceiver, second intermediate results corresponding to the transmit bits, each of at least some of the second intermediate results corresponding to an encoding of a respective subset of multiple bits from amongst the transmit bits, the respective subset of multiple bits including bits corresponding to a respective modulation symbol amongst the modulation symbols to be transmitted by the transceiver; and generating, at the transceiver, the first intermediate results using the second intermediate results, each of at least some of the first intermediate results corresponding to an encoding of a respective set of multiple second intermediate results, the respective set of second intermediate results including second intermediate results that correspond to multiple modulation symbols to be transmitted by the transceiver.

Embodiment 17: The method for error correction encoding of embodiment 16, wherein generating the first intermediate results further comprises generating, at the transceiver, an additional parity bit using the second intermediate results, the additional parity bit corresponding to an encoding of the second intermediate results; and wherein mapping the transmit bits and the parity bits to modulation symbols comprises mapping, by the transceiver according to the modulation technique, the transmit bits, the parity bits, and the additional parity bit to modulation symbols.

Embodiment 18: The method for error correction encoding of embodiment 15, wherein generating the intermediate results corresponding to the transmit bits comprises generating, at the transceiver, exclusive-OR (XOR) results corresponding to the transmit bits, each of at least some of the XOR results corresponding to an XOR of a respective set of multiple bits from amongst the transmit bits, the respective set of multiple bits including bits corresponding to multiple modulation symbols to be transmitted by the transceiver; and wherein encoding the intermediate results corresponding to the transmit bits comprises encoding, by the transceiver according to the FEC code, the XOR results corresponding to the respective sets of multiple bits to generate the parity bits.

Embodiment 19: The method for error correction encoding of embodiment 18, wherein generating the XOR results comprises: generating, by the transceiver, intermediate XOR results corresponding to the transmit bits, each of at least some of the intermediate XOR results corresponding to an XOR of a respective subset of multiple bits from amongst the transmit bits, the respective subset of multiple bits including bits corresponding to a respective modulation symbol amongst the modulation symbols to be transmitted by the transceiver; and generating, by the transceiver, the XOR results using the intermediate XOR results, each of at least some of the XOR results corresponding to an XOR of a respective set of multiple intermediate XOR results, the respective set of intermediate XOR results including intermediate XOR results that correspond to multiple modulation symbols to be transmitted by the transceiver.

Embodiment 20: The method for error correction encoding of embodiment 19, further comprising generating, by the transceiver, an additional parity bit using the intermediate XOR results, the additional parity bit corresponding to an XOR of the intermediate XOR results; and wherein mapping the transmit bits and the parity bits to modulation symbols comprises mapping, by the transceiver according to the modulation technique, the transmit bits, the parity bits, and the additional parity bit to modulation symbols.

Embodiment 21: The method for error correction encoding of any of embodiments 15-20, further comprising: generating, by the transceiver, FEC codewords, each FEC codeword including a respective group of N transmit bits, wherein N is a positive integer greater than one; wherein generating the intermediate results comprises generating, for each of at least some of the FEC codewords, a respective set of intermediate results corresponding to the respective group of N transmit bits; wherein encoding the intermediate results according to the FEC code comprises, for each of the at least some of the FEC codewords, encoding, according to the FEC code, the respective set of intermediate results to generate P parity bits for the FEC codeword, wherein P is a positive integer greater than one; and wherein mapping the transmit bits and the parity bits to modulation symbols comprises mapping, according to the modulation technique, the FEC codewords to the modulation symbols.

Embodiment 22: The method for error correction encoding of embodiment 21, wherein N is 400.

Embodiment 23: The method for error correction encoding of either of embodiments 21 or 222, wherein P is 15.

Embodiment 24: The method for error correction encoding of any of embodiments 15-23, wherein encoding the intermediate results according to the FEC code comprises encoding the intermediate results according to a Bose-Chaudhuri-Hocquenghem (BCH) code to generate the parity bits.

Embodiment 25: The method for error correction encoding of any of embodiments 15-24, wherein mapping the transmit bits and the parity bits to modulation symbols comprises: mapping, according to a pulse amplitude modulation (PAM) technique, the transmit bits and the parity bits to PAM modulation symbols to generate the digital transmit signal.

Embodiment 26: The method for error correction encoding of embodiment 25, wherein mapping the transmit bits and the parity bits to modulation symbols comprises: mapping, according to a 4-level pulse amplitude modulation (PAM4) technique, the transmit bits and the parity bits to PAM4 modulation symbols to generate the digital transmit signal.

Embodiment 27: The method for error correction encoding of any of embodiments 15-26, further comprising: converting, by a digital-to-analog converter (DAC), the digital transmit signal to an analog transmit signal.

Embodiment 28: The method for error correction encoding of embodiment 27, further comprising: generating, by transmit optics that include a laser, an optical transmit signal for transmission via an optical communication medium based on the analog transmit signal.

Embodiment 29: The method for error correction encoding of embodiment 27, further comprising: generating, by a transmitter, an electrical transmit signal for transmission via a communication medium based on the analog transmit signal.

At least some of the various blocks, operations, and techniques described above may be implemented utilizing hardware, a processor executing firmware instructions, a processor executing software instructions, or any combination thereof. When implemented utilizing a processor executing software or firmware instructions, the software or firmware instructions may be stored in any computer readable memory coupled to the processor, such as a RAM, a ROM, a flash memory, etc. The software or firmware instructions may include machine readable instructions that, when executed by one or more processors, cause the one or more processors to perform various acts.

When implemented in hardware, the hardware may comprise one or more of discrete components, an integrated circuit, an application-specific integrated circuit (ASIC), a programmable logic device (PLD), etc.

While the present invention has been described with reference to specific examples, which are intended to be illustrative only and not to be limiting of the invention, changes, additions and/or deletions may be made to the disclosed embodiments without departing from the scope of the invention.

What is claimed is:

1. Transceiver circuitry for communicating via a communication medium, comprising:
a communication interface configured to receive transmit bits for transmission via a communication medium;
digital signal processing (DSP) circuitry including:
encoding circuitry configured to generate intermediate results corresponding to the transmit bits, each of at least some of the intermediate results corresponding to an encoding of a respective set of multiple bits from amongst the transmit bits, the respective set of multiple bits including bits corresponding to multiple modulation symbols to be transmitted by the transceiver,
forward error correction (FEC) encoder circuitry configured to encode, according to an FEC code, the intermediate results corresponding to the respective sets of multiple bits to generate parity bits, and
mapping circuitry configured to map, according to a modulation technique, the transmit bits and the parity bits to modulation symbols to generate a digital transmit signal; and
a digital-to-analog converter (DAC) configured to convert the digital transmit signal to an analog transmit signal.

2. The transceiver circuitry of claim 1, wherein the intermediate results are first intermediate results, and wherein the encoding circuitry comprises:
first circuitry configured to generate second intermediate results corresponding to the transmit bits, each of at least some of the second intermediate results corresponding to an encoding of a respective subset of multiple bits from amongst the transmit bits, the respective subset of multiple bits including bits corresponding to a respective modulation symbol amongst the modulation symbols to be transmitted by the transceiver; and
second circuitry configured to generate the first intermediate results using the second intermediate results, each of at least some of the first intermediate results corresponding to an encoding of a respective set of multiple second intermediate results, the respective set of second intermediate results including second intermediate results that correspond to multiple modulation symbols to be transmitted by the transceiver.

3. The transceiver circuitry of claim 2, wherein the encoding circuitry further comprises third circuitry configured to generate an additional parity bit using the second intermediate results, the additional parity bit corresponding to an encoding of the second intermediate results; and
wherein the mapping circuitry is configured to map, according to the modulation technique, the transmit bits, the parity bits, and the additional parity bit to the modulation symbols to generate the digital transmit signal.

4. The transceiver circuitry of claim 1, wherein the encoding circuitry comprises exclusive-OR (XOR) calculation circuitry configured to generate XOR results corresponding to the transmit bits, each of at least some of the XOR results corresponding to an XOR of a respective set of multiple bits from amongst the transmit bits, the respective set of multiple bits including bits corresponding to multiple modulation symbols to be transmitted by the transceiver; and
wherein the FEC encoder circuitry configured to encode, according to the FEC code, the XOR results corresponding to the respective sets of multiple bits to generate the parity bits.

5. The transceiver circuitry of claim 4, wherein the XOR calculation circuitry comprises:
first circuitry configured to generate intermediate XOR results corresponding to the transmit bits, each of at least some of the intermediate XOR results corresponding to an XOR of a respective subset of multiple bits from amongst the transmit bits, the respective subset of multiple bits including bits corresponding to a respective modulation symbol amongst the modulation symbols to be transmitted by the transceiver; and
second circuitry configured to generate the XOR results using the intermediate XOR results, each of at least some of the XOR results corresponding to an XOR of a respective set of multiple intermediate XOR results, the respective set of intermediate XOR results including intermediate XOR results that correspond to multiple modulation symbols to be transmitted by the transceiver.

6. The transceiver circuitry of claim 5, wherein the XOR calculation circuitry further comprises third circuitry configured to generate an additional parity bit using the intermediate XOR results, the additional parity bit corresponding to an XOR of the intermediate XOR results; and
wherein the mapping circuitry is configured to map, according to the modulation technique, the transmit bits, the parity bits, and the additional parity bit to the modulation symbols to generate the digital transmit signal.

7. The transceiver circuitry of claim 1, wherein:
the DSP circuitry is configured to generate FEC codewords, each FEC codeword including a respective group of N transmit bits, wherein N is a positive integer greater than one;
the encoding circuitry is configured to generate, for each of at least some of the FEC codewords, a respective set of intermediate results corresponding to the respective group of N transmit bits;
the FEC encoder circuitry is configured to, for each of the at least some of the FEC codewords, encode, according to the FEC code, the respective set of intermediate results to generate P parity bits for the FEC codeword, wherein P is a positive integer greater than one; and
the mapping circuitry configured to map, according to the modulation technique, the FEC codewords to the modulation symbols.

8. The transceiver circuitry of claim 7, wherein N is 400.

9. The transceiver circuitry of claim 7, wherein P is 15.

10. The transceiver circuitry of claim 1, wherein the FEC encoder circuitry is configured to encode the intermediate results according to a Bose-Chaudhuri-Hocquenghem (BCH) code to generate the parity bits.

11. The transceiver circuitry of claim 1, wherein the mapping circuitry is configured to:
map, according to a pulse amplitude modulation (PAM) technique, the transmit bits and the parity bits to PAM modulation symbols to generate the digital transmit signal.

12. The transceiver circuitry of claim 11, wherein the mapping circuitry is configured to:
map, according to a 4-level pulse amplitude modulation (PAM4) technique, the transmit bits and the parity bits to PAM4 modulation symbols to generate the digital transmit signal.

13. The transceiver circuitry of claim 1, further comprising:
transmit optics coupled to the DAC, the transmit optics including a laser, the transmit optics configured to generate, based on the analog transmit signal and an output of the laser, an optical transmit signal for transmission via an optical communication medium.

14. A method for error correction encoding in a communication system, the method comprising:
receiving, at a transceiver, transmit bits for transmission via a communication medium;
generating, at the transceiver, intermediate results corresponding to the transmit bits, each of at least some of the intermediate results corresponding to an encoding of a respective set of multiple bits from amongst the transmit bits, the respective set of multiple bits including bits corresponding to multiple modulation symbols to be transmitted by the transceiver;
encoding, by the transceiver according to a forward error correction (FEC) code, the intermediate results corresponding to the transmit bits to generate parity bits; and
mapping, by the transceiver according to a modulation technique, the transmit bits and the parity bits to modulation symbols to be transmitted by the transceiver.

15. The method for error correction encoding of claim 14, wherein the intermediate results are first intermediate results, and wherein generating the first intermediate results comprises:
generating, at the transceiver, second intermediate results corresponding to the transmit bits, each of at least some of the second intermediate results corresponding to an encoding of a respective subset of multiple bits from amongst the transmit bits, the respective subset of multiple bits including bits corresponding to a respective modulation symbol amongst the modulation symbols to be transmitted by the transceiver; and
generating, at the transceiver, the first intermediate results using the second intermediate results, each of at least some of the first intermediate results corresponding to an encoding of a respective set of multiple second intermediate results, the respective set of second intermediate results including second intermediate results that correspond to multiple modulation symbols to be transmitted by the transceiver.

16. The method for error correction encoding of claim 15, wherein generating the first intermediate results further comprises generating, at the transceiver, an additional parity bit using the second intermediate results, the additional parity bit corresponding to an encoding of the second intermediate results; and
wherein mapping the transmit bits and the parity bits to modulation symbols comprises mapping, by the transceiver according to the modulation technique, the transmit bits, the parity bits, and the additional parity bit to modulation symbols.

17. The method for error correction encoding of claim 14, wherein generating the intermediate results corresponding to the transmit bits comprises generating, at the transceiver, exclusive-OR (XOR) results corresponding to the transmit bits, each of at least some of the XOR results corresponding to an XOR of a respective set of multiple bits from amongst the transmit bits, the respective set of multiple bits including bits corresponding to multiple modulation symbols to be transmitted by the transceiver; and
wherein encoding the intermediate results corresponding to the transmit bits comprises encoding, by the transceiver according to the FEC code, the XOR results corresponding to the respective sets of multiple bits to generate the parity bits.

18. The method for error correction encoding of claim 17, wherein generating the XOR results comprises:
generating, by the transceiver, intermediate XOR results corresponding to the transmit bits, each of at least some of the intermediate XOR results corresponding to an XOR of a respective subset of multiple bits from amongst the transmit bits, the respective subset of multiple bits including bits corresponding to a respective modulation symbol amongst the modulation symbols to be transmitted by the transceiver; and
generating, by the transceiver, the XOR results using the intermediate XOR results, each of at least some of the XOR results corresponding to an XOR of a respective set of multiple intermediate XOR results, the respective set of intermediate XOR results including intermediate XOR results that correspond to multiple modulation symbols to be transmitted by the transceiver.

19. The method for error correction encoding of claim 18, further comprising generating, by the transceiver, an additional parity bit using the intermediate XOR results, the additional parity bit corresponding to an XOR of the intermediate XOR results; and
wherein mapping the transmit bits and the parity bits to modulation symbols comprises mapping, by the transceiver according to the modulation technique, the transmit bits, the parity bits, and the additional parity bit to modulation symbols.

20. The method for error correction encoding of claim 11, further comprising:
generating, by the transceiver, FEC codewords, each FEC codeword including a respective group of N transmit bits, wherein N is a positive integer greater than one;
wherein generating the intermediate results comprises generating, for each of at least some of the FEC codewords, a respective set of intermediate results corresponding to the respective group of N transmit bits;
wherein encoding the intermediate results according to the FEC code comprises, for each of the at least some of the FEC codewords, encoding, according to the FEC code, the respective set of intermediate results to generate P parity bits for the FEC codeword, wherein P is a positive integer greater than one; and
wherein mapping the transmit bits and the parity bits to modulation symbols comprises mapping, according to the modulation technique, the FEC codewords to the modulation symbols.

21. The method for error correction encoding of claim 20, wherein N is 400.

22. The method for error correction encoding of claim 20, wherein P is 15.

23. The method for error correction encoding of claim 14, wherein encoding the intermediate results according to the FEC code comprises encoding the intermediate results according to a Bose-Chaudhuri-Hocquenghem (BCH) code to generate the parity bits.

24. The method for error correction encoding of claim 14, wherein mapping the transmit bits and the parity bits to modulation symbols comprises:
mapping, according to a pulse amplitude modulation (PAM) technique, the transmit bits and the parity bits to PAM modulation symbols to generate the digital transmit signal.

25. The method for error correction encoding of claim 24, wherein mapping the transmit bits and the parity bits to modulation symbols comprises:
mapping, according to a 4-level pulse amplitude modulation (PAM4) technique, the transmit bits and the parity bits to PAM4 modulation symbols to generate the digital transmit signal.

26. The method for error correction encoding of claim 14, further comprising:
converting, by a digital-to-analog converter (DAC), the digital transmit signal to an analog transmit signal.

27. The method for error correction encoding of claim 26, further comprising:
generating, by transmit optics that include a laser, an optical transmit signal for transmission via an optical communication medium based on the analog transmit signal.
